(19) United States
(12) Patent Application Publication
(10) Pub. No.: US 2026/0082816 A1
(43) Pub. Date: Mar. 19, 2026

(54) MAGNETIC STORAGE DEVICE

(71) Applicant: Kioxia Corporation, Tokyo (JP)

(72) Inventors: Masaru TOKO, Kawasaki Kanagawa (JP); Youngmin EEH, Yokohama Kanagawa (JP); Taiga ISODA, Yokohama Kanagawa (JP); Hideyuki SUGIYAMA, Kawasaki Kanagawa (JP); Masahiko NAKAYAMA, Yokohama Kanagawa (JP); Rina TAKASHIMA, Machida Tokyo (JP)

(21) Appl. No.: 19/076,936

(22) Filed: Mar. 11, 2025

(30) Foreign Application Priority Data
Sep. 17, 2024 (JP) 2024-160361

(51) Int. Cl. H10N 50/85; H01F 10/16; H10B 61/00; H10N 50/10

(52) U.S. Cl. CPC H10N 50/85; H01F 10/16; H10B 61/10; H10N 50/10

(57) ABSTRACT

A magnetic storage device includes a first magnetic layer; a first predetermined element containing layer containing O and containing at least one first predetermined element selected from Sc, Y, Ti, Zr, Hf, Al, Si, La, Ce, Pr, Nd, Pm, Sm, Eu, Gd, Tb, Ho, Dy, Er, Yb, and Lu; a second magnetic layer provided between the first magnetic layer and the first predetermined element containing layer; a second predetermined element containing layer provided between the first predetermined element containing layer and the second magnetic layer, wherein the second predetermined element containing layer substantially contains only at least one second predetermined element selected from P, As, Sb, Bi, S, Se, and Te; and a non-magnetic layer provided between the first magnetic layer and the second magnetic layer.

### CROSS-REFERENCE TO RELATED APPLICATION

This application is based upon and claims the benefit of priority from Japanese Patent Application No. 2024-160361, filed Sep. 17, 2024, the entire contents of which are incorporated herein by reference.

### FIELD

An embodiment described herein relates generally to a magnetic storage device.

### BACKGROUND

A magnetic storage device has been proposed in which a plurality of magnetoresistance effect elements are integrated on a semiconductor substrate.

### BRIEF DESCRIPTION OF THE DRAWINGS

FIG. 1 is a cross-sectional view schematically illustrating a basic configuration of a magnetic storage device according to a first embodiment.

FIG. 2 is a cross-sectional view schematically illustrating a basic configuration of a modification of the magnetic storage device according to the first embodiment.

### DETAILED DESCRIPTION

A magnetic storage device including a magnetoresistance effect element having advantageous characteristics is provided.

In general, according to a first embodiment, a magnetic storage device includes a first magnetic layer; a first predetermined element containing layer containing oxygen (O) and containing at least one first predetermined element selected from scandium (Sc), yttrium (Y), titanium (Ti), zirconium (Zr), hafnium (Hf), aluminum (Al), silicon (Si), lanthanum (La), cerium (Ce), praseodymium (Pr), neodymium (Nd), promethium (Pm), samarium (Sm), europium (Eu), gadolinium (Gd), terbium (Tb), holmium (Ho), dysprosium (Dy), erbium (Er), ytterbium (Yb), and lutetium (Lu); a second magnetic layer provided between the first magnetic layer and the first predetermined element containing layer; a second predetermined element containing layer provided between the first predetermined element containing layer and the second magnetic layer, wherein the second predetermined element containing layer substantially contains only at least one second predetermined element selected from phosphorus (P), arsenic (As), antimony (Sb), bismuth (Bi), sulfur (S), selenium (Se), and tellurium (Te); and a non-magnetic layer provided between the first magnetic layer and the second magnetic layer.

Hereinafter, an embodiment will be described with reference to the drawings.

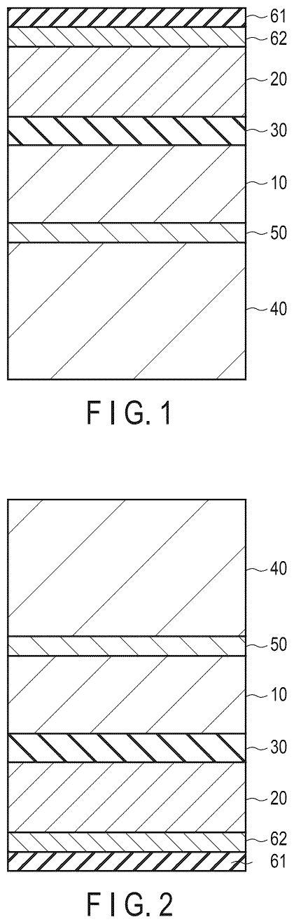

FIG. 1 is a cross-sectional view schematically illustrating a basic configuration of a magnetic storage device according to a first embodiment.

A structure illustrated in FIG. 1 is provided on a lower structure (not illustrated) including a semiconductor substrate (not illustrated), and functions as a magnetoresistance effect element. Specifically, the magnetoresistance effect element functions as an MTJ (magnetic tunnel junction) element with perpendicular magnetization.

The magnetic storage device of the first embodiment illustrated in FIG. 1 includes a reference layer 10, a storage layer 20, a tunnel barrier layer 30, a shift canceling layer 40, an intermediate layer 50, a first predetermined element containing layer 61, and a second predetermined element containing layer 62, and has a stacked structure in which these layers 10 to 62 are stacked. The reference layer 10, the storage layer 20, and the shift canceling layer 40 are magnetic, and the tunnel barrier layer 30 and the intermediate layer 50 are non-magnetic.

More specifically, the reference layer 10, the storage layer 20, the tunnel barrier layer 30, the intermediate layer 50, and the second predetermined element containing layer 62 are provided between the shift canceling layer 40 and the first predetermined element containing layer 61, the storage layer 20 is provided between the reference layer 10 and the first predetermined element containing layer 61, the second predetermined element containing layer 62 is provided between the first predetermined element containing layer 61 and the storage layer 20, the tunnel barrier layer 30 is provided between the reference layer 10 and the storage layer 20, the reference layer 10 is provided between the tunnel barrier layer 30 and the shift canceling layer 40, and the intermediate layer 50 is provided between the reference layer 10 and the shift canceling layer 40.

The reference layer 10 is a ferromagnetic layer with a fixed magnetization direction, and has perpendicular magnetization. That is, the magnetization direction of the reference layer 10 is perpendicular to an upper or lower surface of the reference layer 10. The reference layer 10 contains at least one element selected from iron (Fe) and cobalt (Co), and may further contain boron (B). For example, in the first embodiment, the reference layer 10 may be formed by a CoFeB layer containing Co, Fe, and B.

The storage layer 20 is a ferromagnetic layer with a variable magnetization direction, and has perpendicular magnetization. That is, the magnetization direction of the storage layer 20 is perpendicular to an upper or lower surface of the storage layer 20. The storage layer 20 contains at least one element selected from iron (Fe) and cobalt (Co), and may further contain boron (B). For example, in the first embodiment, the storage layer 20 may be formed by a CoFeB layer containing Co, Fe, and B.

The tunnel barrier layer 30 is provided between the reference layer 10 and the storage layer 20, a lower surface of the tunnel barrier layer 30 being in contact with the reference layer 10, and an upper surface of the tunnel barrier layer 30 being in contact with the storage layer 20. The tunnel barrier layer 30 is an insulating layer, and is formed by an MgO layer containing magnesium (Mg) and oxygen (O).

The shift canceling layer 40 is a ferromagnetic layer with a fixed magnetization direction, and has perpendicular magnetization. That is, the magnetization direction of the shift canceling layer 40 is perpendicular to an upper or lower surface of the shift canceling layer 40. The shift canceling layer 40 has a magnetization direction antiparallel to the magnetization direction of the reference layer 10, and has a function of canceling the magnetic field applied to the storage layer 20 from the reference layer 10. In addition, the shift canceling layer 40 has a superlattice structure in which cobalt (Co) and platinum (Pt) are alternately stacked.

The intermediate layer 50 includes, for example, an iridium (Ir) layer or a ruthenium (Ru) layer, and SAF coupling (synthetic antiferromagnetic coupling) is provided between the reference layer 10 and the shift canceling layer 40 via the intermediate layer 50.

The first predetermined element containing layer 61 is provided above the storage layer 20, and functions as a part of a cap layer.

The first predetermined element containing layer 61 contains at least one first predetermined element selected from scandium (Sc), yttrium (Y), titanium (Ti), zirconium (Zr), hafnium (Hf), aluminum (Al), silicon (Si), lanthanum (La), cerium (Ce), praseodymium (Pr), neodymium (Nd), promethium (Pm), samarium (Sm), europium (Eu), gadolinium (Gd), terbium (Tb), holmium (Ho), dysprosium (Dy), erbium (Er), ytterbium (Yb), and lutetium (Lu), and contains oxygen (O). That is, the first predetermined element containing layer 61 is an oxide layer containing at least one first predetermined element and oxygen (O).

The second predetermined element containing layer 62 is provided between the storage layer 20 and the first predetermined element containing layer 61, and functions as a part of the cap layer. An upper surface of the second predetermined element containing layer 62 is in contact with the first predetermined element containing layer 61, and a lower surface of the second predetermined element containing layer 62 is in contact with the storage layer 20.

The second predetermined element containing layer 62 substantially contains only at least one second predetermined element selected from phosphorus (P), arsenic (As), antimony (Sb), bismuth (Bi), sulfur (S), selenium (Se), and tellurium (Te). That is, the second predetermined element containing layer 62 may be substantially formed of only one second predetermined element, or may be substantially formed of only two or more second predetermined elements. It is preferable for the second predetermined element containing layer 62 to have a thin thickness of 1 nm or less.

Note that with respect to a layer including one or more intended elements, “substantially contains” and “substantially formed of” mean that the layer is exclusively constituted of the one or more intended elements but for possible inclusion of a trace amount of one or more other elements. With respect to such other elements, a “trace amount” means an amount that is so small that while such other elements may be detectable, they may be difficult to measure precisely and have minimal to no impact on properties of a layer.

As described below, in the first embodiment, by providing the first predetermined element containing layer 61 and the second predetermined element containing layer 62, the perpendicular magnetic anisotropy of the storage layer 20 can be increased. Increasing the perpendicular magnetic anisotropy of the storage layer 20 allows for decreasing the thickness of the storage layer 20 without compromising the magnetic stability of the storage layer 20, so the size of the magnetoresistance effect element may be reduced. Accordingly, the magnetoresistance effect element having advantageous characteristics can be obtained.

In order to obtain a magnetoresistance effect element having advantageous characteristics, it is important to increase the perpendicular magnetic anisotropy of a storage layer. However, as the size of a magnetoresistance effect element is decreased, it becomes difficult to obtain a storage layer with high perpendicular magnetic anisotropy.

In the first embodiment, the second predetermined element containing layer 62 is provided adjacent to the storage layer 20. The second predetermined element is selected from P, As, Sb, and Bi, which are semimetal pnictogen elements, and from S, Se, and Te, which are chalcogen elements. The second predetermined element containing layer 62 substantially contains only at least one second predetermined element, and by providing such second predetermined element containing layer 62 adjacent to the storage layer 20, the interface magnetic anisotropy of the storage layer 20 can be increased.

However, without the first predetermined element containing layer 61, there would be a possibility that a stable second predetermined element containing layer 62 would not be formed by only providing the second predetermined element containing layer 62 on the storage layer 20.

In the first embodiment, the first predetermined element containing layer 61 is provided adjacent to the second predetermined element containing layer 62. As already described, the first predetermined element containing layer 61 is an oxide layer containing at least one first predetermined element and oxygen (O). By providing such first predetermined element containing layer 61 adjacent to the second predetermined element containing layer 62, the second predetermined element containing layer 62 can be stabilized. Specifically, since the at least one first predetermined element contained in the first predetermined element containing layer 61 and the at least one second predetermined element contained in the second predetermined element containing layer 62 are bonded to each other, it becomes possible to form the second predetermined element containing layer 62 with a flat upper surface that avoids degradation of magnetic properties thereof, and thus stabilize the second predetermined element containing layer 62.

Accordingly, in the first embodiment, the second predetermined element containing layer 62 can be stabilized by the first predetermined element containing layer 61, and it becomes possible to increase the perpendicular magnetic anisotropy of the storage layer 20 by the stabilized second predetermined element containing layer 62.

FIG. 2 is a cross-sectional view schematically illustrating a basic configuration of a modification of the magnetic storage device according to the first embodiment.

The basic structure of the modification is similar to the structure of the first embodiment. However, although the magnetoresistance effect element of the first embodiment is a “top-free” type magnetoresistance effect element in which the storage layer 20 is located on an upper layer side of the reference layer 10, the modification is a “bottom-free” type magnetoresistance effect element in which the storage layer 20 is located on a lower layer side of the reference layer 10. Therefore, the stacking order of the layers 10 to 62 in the modification is reversed from the stacking order of the layers 10 to 62 of the first embodiment.

Note that, although the first predetermined element containing layer 61 and the second predetermined element containing layer 62 function as the cap layer in the first embodiment illustrated in FIG. 1, the first predetermined element containing layer 61 and the second predetermined element containing layer 62 function as a base layer in the modification.

In this manner, the basic structure of the modification is similar to the structure of the first embodiment, and the modification can also obtain effects similar to the effects of the first embodiment.

While an embodiment has been described, this embodiment has been presented by way of example only, and is not intended to limit the scope of the invention. Indeed, the novel devices and methods described herein may be embodied in a variety of other forms; furthermore, various omissions, substitutions and changes in the form of the embodiment described herein may be made without departing from the spirit of the invention. The accompanying claims and their equivalents are intended to cover such forms or modification as would fall within the scope and spirit of the invention.

What is claimed is:

1. A magnetic storage device comprising:
a first magnetic layer;
a first predetermined element containing layer containing oxygen (O) and containing at least one first predetermined element selected from scandium (Sc), yttrium (Y), titanium (Ti), zirconium (Zr), hafnium (Hf), aluminum (Al), silicon (Si), lanthanum (La), cerium (Ce), praseodymium (Pr), neodymium (Nd), promethium (Pm), samarium (Sm), europium (Eu), gadolinium (Gd), terbium (Tb), holmium (Ho), dysprosium (Dy), erbium (Er), ytterbium (Yb), and lutetium (Lu);
a second magnetic layer provided between the first magnetic layer and the first predetermined element containing layer;
a second predetermined element containing layer provided between the first predetermined element containing layer and the second magnetic layer, wherein the second predetermined element containing layer substantially contains only at least one second predetermined element selected from phosphorus (P), arsenic (As), antimony (Sb), bismuth (Bi), sulfur(S), selenium (Se), and tellurium (Te); and
a non-magnetic layer provided between the first magnetic layer and the second magnetic layer.

2. The magnetic storage device of claim 1, wherein the first magnetic layer has a fixed magnetization direction, and the second magnetic layer has a variable magnetization direction.

3. The magnetic storage device of claim 1, wherein the first magnetic layer contains at least one element selected from iron (Fe) and cobalt (Co).

4. The magnetic storage device of claim 3, wherein the first magnetic layer further contains boron (B).

5. The magnetic storage device of claim 1, wherein the second magnetic layer contains at least one element selected from iron (Fe) and cobalt (Co).

6. The magnetic storage device of claim 5, wherein the second magnetic layer further contains boron (B).

7. The magnetic storage device of claim 1, wherein the non-magnetic layer contains magnesium (Mg) and oxygen (O).

8. The magnetic storage device of claim 1, wherein the second predetermined element containing layer is in contact with the first predetermined element containing layer.

9. The magnetic storage device of claim 1, wherein the second predetermined element containing layer is in contact with the second magnetic layer.

10. The magnetic storage device of claim 1, wherein the second magnetic layer is in contact with the non-magnetic layer.

11. The magnetic storage device of claim 1, wherein the first magnetic layer is in contact with the non-magnetic layer.

12. The magnetic storage device of claim 1, wherein the first magnetic layer has perpendicular magnetization.

13. The magnetic storage device of claim 1, wherein the second magnetic layer has perpendicular magnetization.

14. The magnetic storage device of claim 1, wherein the second predetermined element containing layer has a thickness of 1 nm or less.

15. The magnetic storage device of claim 1, further comprising a third magnetic layer having a magnetization direction antiparallel to the magnetization direction of the first magnetic layer, wherein the first magnetic layer is provided between the non-magnetic layer and the third magnetic layer.

16. The magnetic storage device of claim 15, further comprising an intermediate layer including iridium (Ir) or ruthenium (Ru), wherein the intermediate layer is provided between the first magnetic layer and the third magnetic layer.

17. The magnetic storage device of claim 15, wherein the third magnetic layer has perpendicular magnetization.

18. The magnetic storage device of claim 15, wherein the third magnetic layer has a fixed magnetization direction.

19. The magnetic storage device of claim 1, wherein the first predetermined element containing layer is provided on an upper surface of the second predetermined element containing layer.

20. The magnetic storage device of claim 1, wherein the second predetermined element containing layer is provided on an upper surface of the first predetermined element containing layer.
